(19) United States
(12) Patent Application Publication
(10) Pub. No.: US 2026/0179895 A1
(43) Pub. Date: Jun. 25, 2026

(54) Amplifier Arrangement for Ion Optical Device

(71) Applicant: Thermo Fisher Scientific (Bremen) GmbH, Bremen (DE)

(72) Inventors: Philipp Cochems, Bassen (DE); Robert Ostermann, Bremen (DE)

(21) Appl. No.: 19/422,013

(22) Filed: Dec. 16, 2025

(30) Foreign Application Priority Data
Dec. 20, 2024 (GB) 2418828.6

(51) Int. Cl. H01J 49/02; H01J 49/06; H03F 3/45

(52) U.S. Cl. CPC H01J 49/022; H01J 49/061; H01J 49/067; H03F 3/45475; H03F 2203/45114

(57) ABSTRACT

An amplifier arrangement can provide a varying electrode voltage to an ion optical device. The amplifier arrangement comprises: a high-speed amplifier, configured to receive an input to the amplifier arrangement and provide a low voltage output; and a low-speed controllable voltage source, arranged to float on the low voltage output and configured to provide a high voltage output of the amplifier arrangement. The high voltage output of the amplifier arrangement is fed back for control of the high-speed amplifier. The amplifier arrangement beneficially forms part of a power supply for supplying the varying electrode voltage, for example as part of an ion analytical system.

### CROSS REFERENCE TO RELATED APPLICATIONS

This application claims the right of priority under 35 U.S.C. § 119 to United Kingdom Application No. GB2418828.6, filed Dec. 20, 2024, the entire contents of which is incorporated herein by reference.

### TECHNICAL FIELD OF THE DISCLOSURE

The disclosure concerns an amplifier arrangement for providing a varying electrode voltage to an ion optical device, a power supply comprising such an amplifier arrangement and an ion analytical system (for example, a mass spectrometer) comprising such a power supply.

### BACKGROUND TO THE DISCLOSURE

In Time-of-Flight (TOF) mass spectrometry, flight times of ions travelling a known distance are recorded. These flight times are used to determine the mass to charge ratios (m/z) of the ions. In contrast, Fourier Transform Mass Spectrometry (FTMS), including Orbital Trapping mass spectrometry, uses a design in which the ions are cycling in an ion trap. A measured oscillation frequency is used to determine the mass to charge ratios. Hybrid Mass Spectrometry uses different types of mass analyzer for tandem mass spectrometry or MSⁿ. An example of such a mass spectrometer is shown in FIG. 1 of GB2626803A.

In these types of mass spectrometer, orthogonal m/z filtering (termed pre-filtering) is applied to improve the capability of the mass analyzer. This may be used to limit the amount of ions within the analyzer, so as to improve the analyzer performance, or to select certain ion species for further manipulation or fragmentation.

A common pre-filter is a quadrupole mass filter. Ions travelling through a quadrupole ion optical device interact with electric fields generated by superposition of RF and DC voltages. By controlling the ratio of the RF and DC voltages, it is possible to select ions with a certain range of m/z. Other types of multipole mass filter can alternatively be used.

Another technique to increase the analytical performance of a TOF mass analyzer is to select certain ion species within the analyzer by dumping the unwanted ions before they reach the detector. This may be achieved with electrostatic lenses and allows for the other ion species to be reflected several times without interacting with the unwanted species and thus significantly increasing the flight path of the ions to be analyzed.

A further approach uses a prism-like deflector, which can be used to achieve a so-called “zoom-mode”. This is described in GB2617229A and GB2619766A (which also shows a quadrupole mass filter and other ion optical components and devices used for mass selection).

These filtering techniques rely on DC voltages to select a wanted m/z range of ions from those received, for example provided by power supply arrangements as discussed in GB2617229A. Time-variation of the DC voltages is desirably applied very fast; in other words, this demands a short voltage settling time. In the case of a quadrupole mass filter, the variation may occur when selecting different m/z regions for successive scans. A longer switching time will decrease the overall speed of the mass spectrometer. For in-flight ion selection using electrostatic lenses, a minimum voltage switching frequency is necessary to select the ions. The required settling time may vary from very few microseconds (μs) up to a few hundred microseconds. For a quadrupole (or other multipole) mass filter a very precise settling within tens of parts per million (ppm) may be needed.

In these examples, the voltages applied to electrodes are not simply switched on or off, but rather adjusted to varying non-zero potentials in a precise way (such that the variation is made quickly and accurately). The target voltages in these applications are normally in the range of a couple of volts up to a few kV. Existing voltage amplifiers with such a high bandwidth (that is, switching speed) in combination with high voltage output (and high range of voltage output) are complicated and their power consumption is high.

It is therefore desirable to provide a voltage amplifier that can achieve fast and precise adjustment of high voltage output with low power consumption. Such a voltage amplifier would therefore be well suited for use in a power supply for providing a voltage to an electrode of an ion optical device.

### SUMMARY OF THE DISCLOSURE

Against this background, there is provided an amplifier arrangement according to claim 1, a power supply for supplying at least one voltage to an electrode of an ion optical device as defined by claim 10 and an ion analytical system in line with claim 11. Further optional and/or advantageous features are defined in the dependent claims.

The disclosure provides an amplifier design that enables fast and precise adjustment of high voltages with low power consumption. It is based on a composite amplifier design, combining amplifiers with different properties to achieve a combination of wanted properties in one circuit. Specifically, a combination of a high-speed low voltage amplifier to allow precise adjustment (for instance, in steps of one or more tenths or tens of volts) with a low-speed high voltage amplifier (which may be a galvanic isolated power supply) to provide high voltage output (for example, around 1 kV) can realize the combined benefits of both amplifiers. The low-speed high voltage amplifier beneficially floats on the output of the high-speed low voltage amplifier. Advantageously, the output of the low-speed high voltage amplifier is used to control the high-speed low voltage amplifier.

Composite amplifier designs are well known. Examples include: amplifiers to drive high loads in combination with precision amplifiers to achieve a precise load driving; and fast amplifiers in combination with precision amplifiers to achieve high speed and precision at the same time. In all these examples, both amplifiers operate in a common voltage range. In contrast, the disclosed amplifier arrangement is based on two different voltage domains: one high (but slow changing); the other low (but fast). This can be used to supply a DC voltage to ion optics (especially of a mass spectrometer), where a varying high voltage is desirably supplied quickly.

This amplifier arrangement advantageously allows provision of a low cost and power-efficient high voltage power supply. Specifically, the amplifier arrangement: can be manufactured at low cost; has low power consumption (and is therefore power efficient); allows precise control of the output voltage; has fast voltage settling; and readily permits active noise-reduction.

In an example, the high-speed amplifier is a differential amplifier. Then, the amplifier input can be provided to one terminal of the differential amplifier (the positive terminal) and the output of the high voltage power supply can be provided to the other terminal (the negative terminal), optionally through a resistor. This creates a feedback that can be used to regulate the high-speed amplifier output.

The high voltage power supply can be controlled based on the input to the amplifier arrangement and/or the high-speed amplifier output. For instance, the high-speed amplifier output can be amplified (or buffered) and/or used to adjust the amplifier input to generate a control signal for the high voltage power supply.

Implementations of the high voltage power supply may include a voltage-controlled voltage source or a current source with a floating capacitor.

The amplifier arrangement can form part of a power supply for supplying at least one voltage to an electrode of an ion optical device (for instance, a multipole ion guide, mass filter or trap or electrostatic lenses). The ion optical device and power supply can form part of an ion analytical system, for example a mass spectrometer or ion mobility spectrometer. In particular, the disclosure may be especially applicable to a Time of Flight (TOF) mass spectrometer, a hybrid mass spectrometer or a Fourier Transform Mass Spectrometer (FTMS). A particularly advantageously application may be for a variable path length ion analyser, for instance a multi-reflecting (TOF) mass analyser, having an electrostatic lens and/or deflector. The voltage applied to that lens and/or deflector may be selected for injection and/or extraction or (in a “zoom” mode) to reverse ion drift direction.

### BRIEF DESCRIPTION OF THE DRAWINGS

The invention may be put into practice in a number of ways, and preferred embodiments will now be described by way of example only and with reference to the accompanying drawings, in which:

FIG. 1 shows a schematic circuit diagram of a basic amplifier arrangement in accordance with the disclosure;

FIG. 2 depicts a schematic circuit diagram of a more complex amplifier arrangement in accordance with the disclosure with a simple feedback configuration;

FIG. 3 plots theoretical, simulated and measured output voltage against time for an amplifier arrangement in accordance with the disclosure;

FIG. 4 shows a circuit diagram of a first type of high voltage source for use with embodiments in accordance with the disclosure;

FIG. 5 shows a circuit diagram of a second type of high voltage source for use with embodiments in accordance with the disclosure; and

FIG. 6 depicts a schematic circuit diagram of a further amplifier arrangement in accordance with the disclosure with a more sophisticated feedback configuration;

FIG. 7 illustrates schematically an analytical instrument that may be used in conjunction with the approaches described herein;

FIG. 8 shows schematically more detail of a mass spectrometer suitable for performing the approaches of various embodiments;

FIG. 9 illustrates schematically detail of a first exemplary embodiment of a variable path length analyser for use in the mass spectrometer of FIG. 8;

FIG. 10 illustrates schematically detail of a second exemplary embodiment of a variable path length analyser for use in the mass spectrometer of FIG. 8; and

FIG. 11 illustrates schematically a zoom mode of operation for a variable path length analyser.

Use of the same reference sign between different drawings is intended to show the same feature. Drawings should be considered schematic in nature unless described otherwise.

### DETAILED DESCRIPTION OF PREFERRED EMBODIMENTS

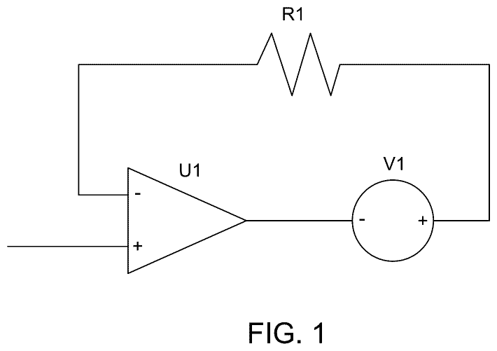

Referring first to FIG. 1, there is shown a schematic circuit diagram of a basic amplifier arrangement in accordance with the disclosure. The amplifier arrangement comprises: a fast low voltage (differential) amplifier U1 that drives the common potential of a high voltage source V1. A voltage feedback resistance R1 measures the overall voltage and closes the regulator loop by providing the high voltage output to the negative input terminal of the low voltage amplifier U1. The input voltage for the amplifier is received at the positive terminal of the low voltage amplifier U1.

Accordingly, the output voltage of the circuit (at the output of high voltage source V1) is the sum of the output voltages generated by the low voltage amplifier U1 and the high voltage source V1. Effectively, the high voltage source V1 floats on the low voltage amplifier U1 output. While the high voltage source V1 is only slowly adjustable, the low voltage amplifier U1 can react quickly, not only changing the output voltage speedily, but also compensating for overshoots, inaccuracies, and ripple introduced by the high voltage source V1.

This circuit concept defines two speed domains: for small voltage variations (say, up to roughly 40V), the fast reaction of the low voltage amplifier U1 is used to change the voltage rapidly and let it settle quickly; for greater adjustment (say, 40V and above), the circuit can react as quickly as the high voltage source V1. Such characteristics fit well to applications in ion optical instructions, particularly mass spectrometry.

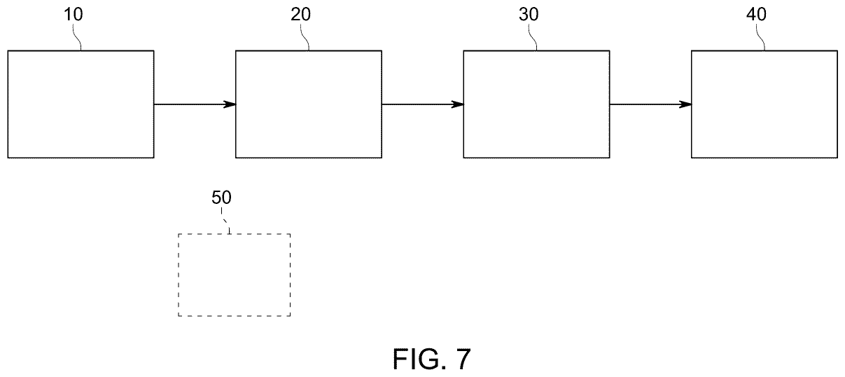

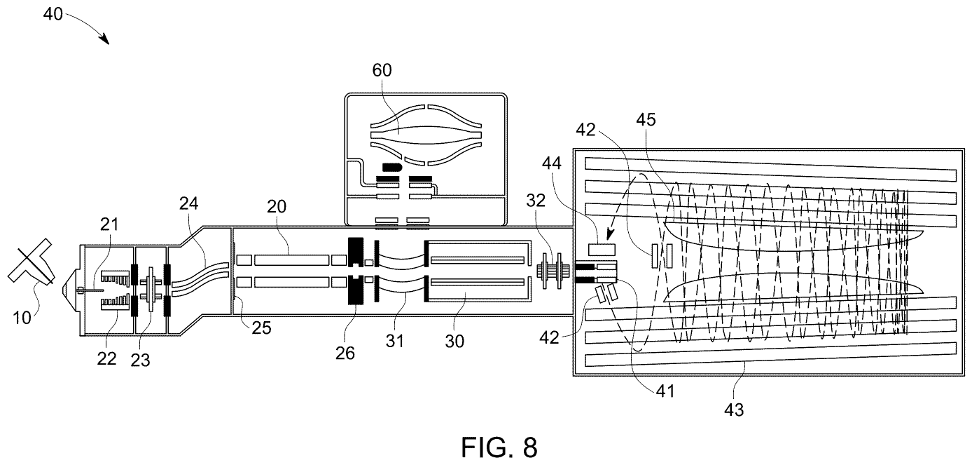

The amplifier arrangement beneficially forms part of a power supply for supplying voltages to electrodes of an ion optical device, for instance as part of an instrument (as detailed with reference to FIG. 7 discussed below, for example). One implementation uses the power supply for the electrodes of a multipole mass filter, for example a quadrupole mass filter (for instance, as shown with reference to FIG. 8 discussed below or FIG. 1 of GB2626803A). In this case, the mass filter is normally operated to scan a whole m/z range in windows. These windows are typically close to each other, so a new isolation can be effected by changing the potentials using a jump of the low voltage amplifier U1 to select the new m/z range. The low voltage amplifier U1 allows the desired output voltage to settle quickly, so that the mass spectrometer can start the analysis with minimal delay between measurements.

During the analysis, the high voltage source V1 changes its voltage output to bring the output of the low voltage amplifier U1 back to zero, such that it becomes ready for the next jump in voltage. The change in output of the high voltage source V1 is thus compensated by the low voltage amplifier U1 output and the power supply output to the electrodes of the quadrupole is stable during this time. After one analysis is completed, the next jump in voltage would be applied.

This way, the scan speed of the quadrupole mass filter can be increased to the point where the high voltage source V1 is continually increasing its voltage, with the low voltage amplifier U1 being operated to keep the overall output stable for the time needed by the mass filter.

The operation of the power supply may be very similar for prefiltering in a ToF mass analyzer (an example of which may include the ToF mass analyzer, specifically a multi-reflection ToF mass analyzer shown in FIG. 8 discussed below or FIG. 1 of GB2626803A).

In general terms, there may thus be considered an amplifier arrangement for providing a varying electrode voltage to an ion optical device. The amplifier arrangement comprises: a high-speed amplifier, configured to receive an input to the amplifier arrangement and provide a low voltage output; and a low-speed controllable voltage source, arranged to float on the low voltage output and configured to provide a high voltage output of the amplifier arrangement. In particular, the high voltage output of the amplifier arrangement is fed back for control of the high-speed amplifier.

In embodiments, the high-speed amplifier comprises (or is) a differential amplifier. For example, the differential amplifier may be configured to receive the input to the amplifier arrangement at a first (negative) input and the high voltage output of the amplifier arrangement at a second (positive) input (optionally through a resistor).

In another aspect, there may be considered a power supply for supplying at least one voltage to an electrode of an ion optical device, comprising an amplifier arrangement as disclosed herein. In a further aspect, there may be considered an ion analytical system comprising: an ion optical device; and the power supply, configured to supply at least one voltage to an electrode of the ion optical device. For example, the ion optical device may be a multipole mass filter or may comprise electrostatic lenses. Advantageously, the ion optical device forms part of a mass spectrometer. The mass spectrometer may be one of: a Time of Flight (TOF) mass spectrometer; a hybrid mass spectrometer; and a Fourier Transform Mass Spectrometer (FTMS).

Further details of specific embodiments will now be discussed. Further reference to the general senses of the disclosure as discussed above will then be made below.

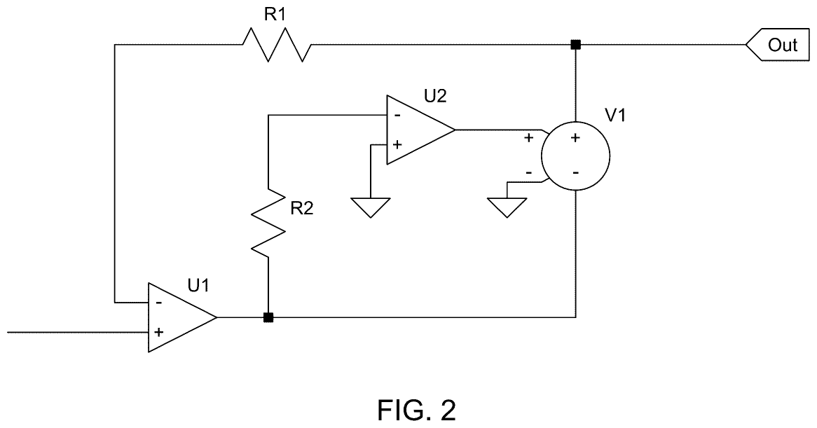

Referring to FIG. 2, there is depicted a schematic circuit diagram of a more complex amplifier arrangement with a simple feedback configuration. Here, the output voltage of the circuit is advantageously regulated by cascaded regulators. An inner regulator, based on second amplifier U2, controls the high voltage source V1. This second amplifier U2 receives the output of the low voltage amplifier U1 via a second resistor R2 at its negative input, with its positive input coupled to ground. The output of the second amplifier U2 is then provided as a control signal to the high voltage source V1.

The inner regulator thus aims for zero volts on the output of the low voltage amplifier U1, to maximize the possible compensation capability of U1. A second regulator (not shown) controls the low voltage amplifier U1, to achieve the desired output voltage at the output of the circuit.

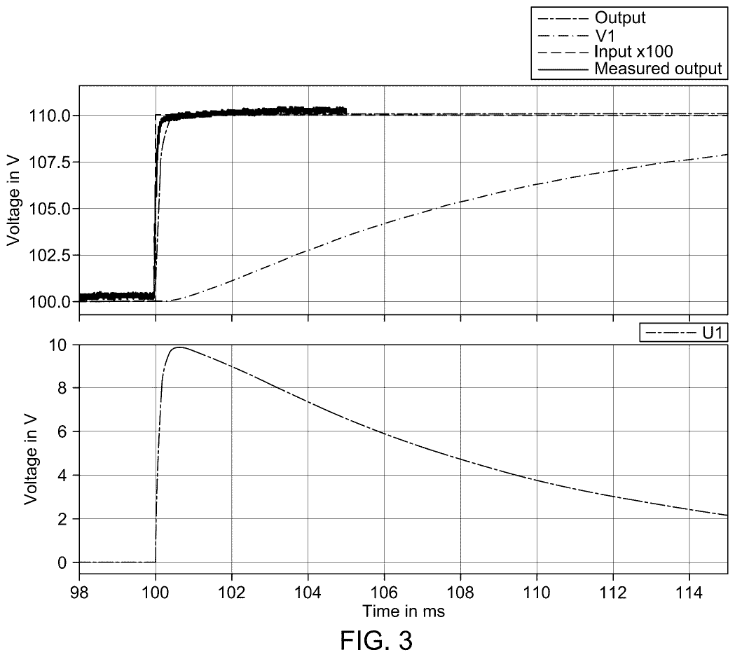

Reference is now made to FIG. 3, which plots theoretical, simulated and measured output voltage against time for an amplifier arrangement in accordance with the disclosure (such as shown in FIGS. 1 and 2) with an example gain of 100. The upper plot shows: the sharp step of the input increased by 100 for direct comparison (from 100.0V to 110.0V exactly at 100 ms); the slow step response for a simulated output of the high voltage source V1, which has not yet reached 110V even at 114 ms (as the high voltage source V1 responds too slowly to follow the jump in the input); the simulated output of the amplifier arrangement, which quickly reaches 110.0V within approximately 0.5 ms; and a measured output from an implementation of the amplifier arrangement.

The bottom plot shows a simulated output voltage of the low voltage amplifier U1, showing how it rises quickly to compensate for the slow response of the high voltage source V1 and then slowly decreases as the output of the high voltage source V1 increases (mirroring the rate of change). As will be appreciated from FIGS. 1 and 2, the arrangement of high voltage source V1 and the low voltage amplifier U1 causes the output of the amplifier arrangement to be the sum of the outputs from these individual circuits. Thus, the output of the low voltage amplifier U1 compensates the output of the high voltage source V1. Effectively, the inner regulator circuit adjusts the high voltage source V1 such that the output of the low voltage amplifier U1 can return to zero, to be prepared for the next fast change in voltage.

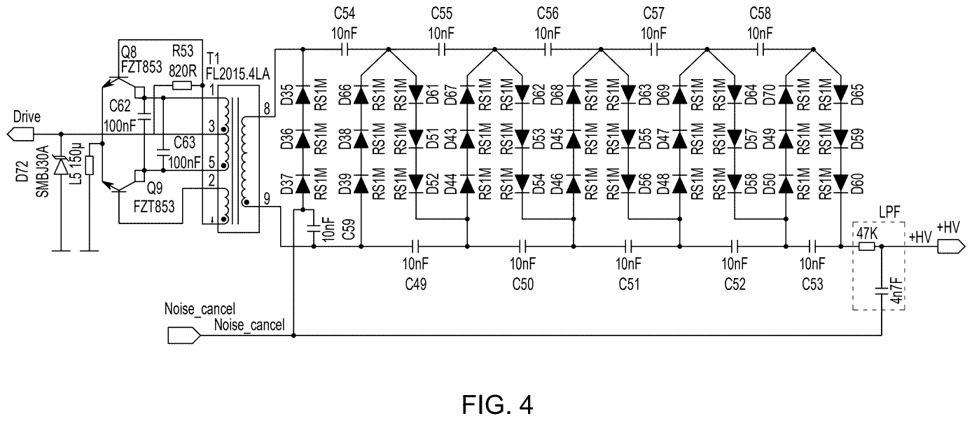

The high voltage source V1 could be implemented using one of many different designs. Referring to FIG. 4, there is shown a circuit diagram of a first exemplary type of high voltage source for use with amplifier arrangements in accordance with the disclosure. This high voltage source is formed by a power supply circuit, in this case a completely galvanic isolated power supply, which provides an output of up to 10 kV in this example. The power supply is formed of a self-resonant circuit coupled to a voltage multiplier via a transformer T1. The power supply receives a “drive” signal, and a rectifier circuit and a “noise_cancel” signal and provides an output signal (“+HV”). The “drive” input against the ground of the circuit would be the voltage control input (and which would also deliver the power). The high voltage is than generated between the “noise_cancel” and “+HV” terminals. The rectifier circuit includes a capacitor and resistor arranged as a low-pass filter LPF.

The transformer T1 creates galvanic isolation. In such a configuration, the “noise_cancel” signal can be driven with the output of the low voltage amplifier U1. The low voltage amplifier U1 provides just small output voltages (in the range of +/−20V +/−12V, +/−10V or +/−5V, for example), but the output voltage may be significantly smaller than this (for instance in tenths or a volt). Therefore, the isolation capability of the transformer T1 does not need to be very high. Normally, it is already covered by the output voltage specifications, which in this example case, would be much higher than 20V.

This power supply, for example, has a self-resonant frequency of about 50 kHz. A large portion of any resulting output ripple is filtered out by the low pass filter LPF. This may create a relatively clean voltage, but it further decreases the response speed of the output voltage. The same is true for any other transformer-based design, no matter if it is self-resonant or actively driven.

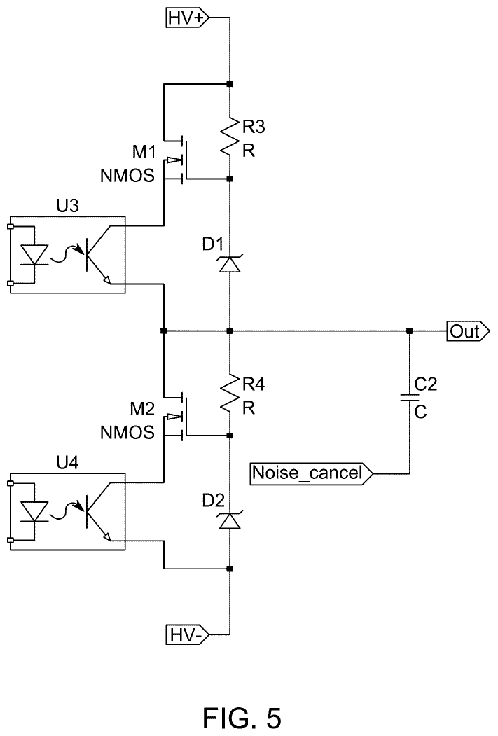

An alternative implementation for the high voltage source V1 may be based on a current source with a floating capacitor. Referring now to FIG. 5, there is shown a circuit diagram of a second exemplary type of high voltage source for use with amplifier arrangements in accordance with the disclosure. This circuit is somewhat simplified, but illustrates key components.

The high voltage source implementation shown in FIG. 5 comprises a cascode stage formed of at least one optocoupler (in this case, two optocouplers U3 and U4) and one or more field effect transistors (in this case, two n-type MOSFET transistors M1 and M2) acting as current sources. The transistors provide voltage-handling and can be stacked to increase the voltage-handling capacity. One arm of this arrangement could also be replaced with a high voltage resistor. One end of a filter capacitor C2 is connected to the output of the low voltage amplifier U1 via the “noise_cancel” terminal. Due to the high impedance of the current sources, the low voltage amplifier U1 can shift the capacitor in a similar way to the isolation transformer-based power supply circuit, described above with reference to FIG. 4.

Amplifier arrangements according to the disclosure may also be operated to reduce noise on the output. If a fast, small jump in voltage is desired (for example, an additional 10V on an initially generated 10 kV), this could be achieved by an increase in the voltage supplied by the low voltage amplifier U1 only. The output of the low voltage amplifier U1 will lift the whole amplifier arrangement output by 10V, while the voltage above the output capacitor of the high voltage source V1 (the capacitor in the low-pass filter LPF of the implementation in FIG. 4 or the capacitor C2 in the implementation of FIG. 5) stays constant. This results in a fast output step. Then, the overall voltage controller will drive the high voltage source V1 to the new desired voltage, as discussed above with reference to FIG. 3. This causes the low voltage amplifier U1 to reduce its output from +10V back to 0V and be prepared for the next jump.

Such a scheme can also be useful to compensate for noise or voltage ripple, as the low voltage amplifier U1 acts as a noise cancellation or jump circuit. Even if a large part of the residual ripple (for instance, from the self-resonant power supply) is filtered out, it can still be in the order of volts on the output. If the low voltage amplifier U1 is a fast amplifier (which can readily be achieved, at least due to the small output voltages desired), it can counteract the ripple and/or cancel out another large portion of the self-resonant residuals. This may enable very low-noise high voltages at up to very high frequencies.

Providing an electrode potential with a low noise on a high voltage is extremely desirable for mass spectrometers, and is becoming increasingly significant for achieving increased repetition rates in new ion optical instruments. As an example, an ion mirror arrangement for a mass analyzer (see FIG. 8 discussed below or FIG. 1 of GB2626803A, for example) may use a 6 kV voltage for proper ion deflection. Stability of this voltage may allow stable m/z measurements. For instance, a voltage shift of 1.5 ppm may cause 1 ppm of m/z shift. Nevertheless, mass analyzers are being designed for very high-speed operation, such that maintaining such voltage stability at DC or very low frequencies limits the repetition rate of the analyzer. This is because ion travel times may be from tens of microseconds to single digit milliseconds and the stability in these time scales therefore becomes limiting. It is also desirable for every spectrum to be used as an analytical result and this prevents averaging the higher frequency noise out by averaging spectra.

GB2630325A describes how the post regulation of the high voltage supply may be implemented to reach such stabilities, although it does not consider response speed. The present disclosure may be used to provide a precise and low noise high voltage output. For many applications, the need for a separate post regulator behind the high voltage supply, as discussed in GB2630325A, may be reduced or eliminated.

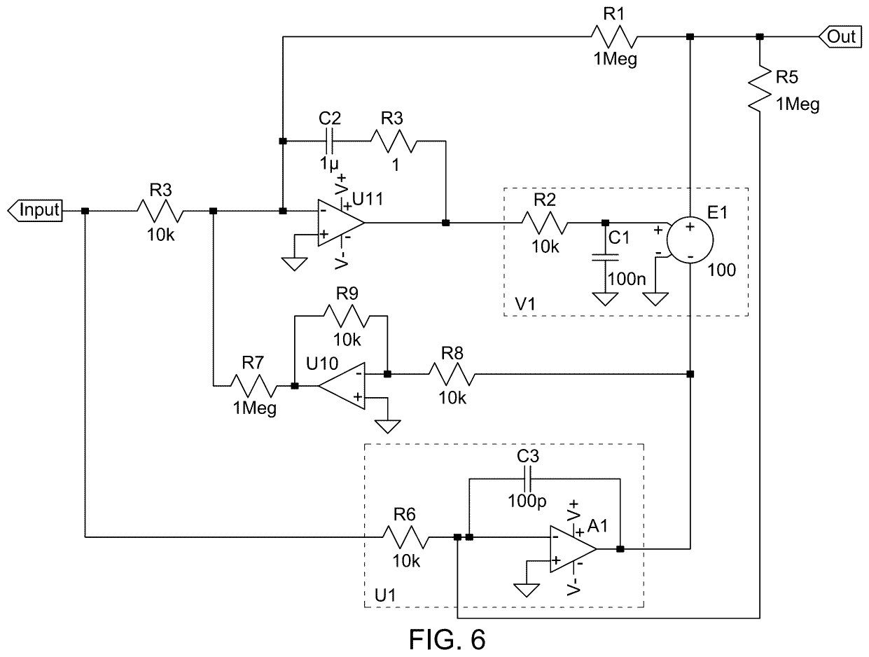

Next referring to FIG. 6, there is depicted a schematic circuit diagram of a further example amplifier arrangement in accordance with the disclosure with a more sophisticated feedback configuration. This circuit shows that the low voltage amplifier U1 and the high voltage source V1 are typically not independently controlled.

In this arrangement, the high voltage source V1 comprises a power supply E1 together with an input low pass filter formed by a resistor R2 and capacitor C1. The low voltage amplifier U1 for providing a fast compensation voltage, is formed by an amplifier A1 with an input resistor R6 and feedback capacity C3. It can be seen that the amplifier arrangement output is the sum of the output of the low voltage amplifier U1 and the output of the high voltage source V1.

The power supply E1 has a slow control circuit comprising control amplifier U11 which receives a feedback signal via feedback resistor R1. The faster, low voltage amplifier U1 and has also a second feedback resistor R5. This could be combined in a real circuit, to have less high voltage dividers on the schematic.

In accordance with this control approach, both the low voltage amplifier U1 and the high voltage source V1 try to follow the input and both are in a feedback loop with the output.

A first controller around the low voltage amplifier U1, using second feedback resistor R5, directly tries to reach the desired output. Control amplifier U11, which controls the high voltage source V1, similarly tries to reach the desired output. To balance these control loops, a connection is made between the output of the low voltage amplifier U1 to the (negative) input of the control amplifier U11 via the circuit around a feedback amplifier U10, comprising input resistor R8, further feedback resistor R9 and output resistor R7. The circuit around the feedback amplifier U10 creates an additional error signal for the control amplifier U11, which leads the feedback amplifier U10 to adjust (increase or decrease) the input voltage to the high voltage source V1 until the output of the low voltage amplifier U1 reaches zero again. In this approach, the output voltage of the low voltage amplifier U1 stays within its voltage range for smaller jumps, whilst the overall output of the amplifier arrangement maintains the desired output voltage.

Returning to the general senses of the disclosure discussed above, additional details may be considered. Specifically, the low-speed controllable voltage source may be configured to be controlled by a control signal derived from the input to the amplifier arrangement and/or the low voltage output of the high-speed amplifier. In particular, the control signal may be derived from the input to the amplifier arrangement adjusted by a signal based on the low voltage output of the high-speed amplifier. For example, a second (control) amplifier may be configured to receive a signal based on the low voltage output of the high-speed amplifier as an input and generate the control signal based on the received signal. The signal based on the low voltage output of the high-speed amplifier may be generated by a further (feedback) amplifier, configured to receive the low voltage output of the high-speed amplifier as an input. Then, the second amplifier may be configured to receive the input to the amplifier arrangement adjusted by the signal based on the low voltage output of the high-speed amplifier (with both the input to the amplifier arrangement and the signal based on the low voltage output of the high-speed amplifier being provided to a common node).

In embodiments, the low-speed controllable voltage source comprises a galvanic isolated power supply. For example, the low-speed controllable voltage source may comprise a voltage-controlled voltage source. Alternatively, the low-speed controllable voltage source may comprise a current source with a floating capacitor.

A wide range of designs for the low voltage amplifier U1 are possible. Typically, a fast operational amplifier is used with a buffer, to increase the drive capability.

FIG. 7 illustrates schematically an analytical instrument, such as a mass spectrometer, that may be used in conjunction with the approaches described herein. As shown in FIG. 7, the instrument includes an ion source 10, a mass filter 20, a fragmentation device 30, and a mass analyser 40.

The ion source 10 is configured to generate ions from a sample. The ion source 10 may be coupled to a separation device (not shown) such as a liquid chromatography (LC) separation device, a gas chromatography (GC) separation device, or a capillary electrophoresis separation device, and the like, such that the sample which is ionised in the ion source 10 comes from the separation device. The ion source 10 can be any suitable ion source, such as an electrospray ionisation (ESI) ion source, an atmospheric pressure ionisation (API) ion source, a chemical ionisation ion source, an electron impact (EI) ion source, or similar. Numerous other types of ionisation are possible.

The analytical instrument may additionally or alternatively include an ion separation device (not shown) arranged downstream of the ion source and configured to separate samples ions according to a physico-chemical property. For example, the instrument may include an ion mobility (IM) separator, a differential ion mobility separator, or a device configured to separate ions according to their mass to charge ratio (m/z)).

The mass filter 20 is arranged downstream of the ion source 10 and is configured to receive ions from the ion source 10 (optionally via the ion separation device). The mass filter 20 is configured to filter the received ions according to their mass to charge ratio (m/z). The mass filter 20 may be configured such that received ions having m/z within an m/z transmission window (or “isolation window”) of the mass filter are onwardly transmitted by the mass filter, while received ions having m/z outside the m/z transmission window are attenuated by the mass filter, i.e. are not onwardly transmitted by the mass filter. The width and/or the centre m/z of the transmission window may be controllable (variable), e.g. by suitable control of RF and/or DC voltage(s) applied to electrodes of the mass filter 20. Thus, for example, the mass filter 20 may be operable in a transmission mode of operation, whereby most or all ions within a relatively wide m/z window are onwardly transmitted by the mass filter 20, and a filtering mode of operation, whereby only ions within a relatively narrow m/z window (centred at a desired m/z) are onwardly transmitted by the mass filter 20. The mass filter 20 can be any suitable type of mass filter, such as a quadrupole mass filter.

The fragmentation device 30 is arranged downstream of the mass filter 20 and is configured to receive most or all ions transmitted by the mass filter 20. The fragmentation device 30 may be configured to selectively fragment some or all of the received ions, i.e. so as to produce fragment ions. The fragmentation device 30 may be operable in a fragmentation mode of operation, whereby most or all received ions are fragmented so as to produce fragment ions (which may then be onwardly transmitted from the fragmentation device 30), and a non-fragmentation mode of operation, whereby most or all received ions are onwardly transmitted without being (deliberately) fragmented. It would also be possible for a non-fragmentation mode of operation to be implemented by causing ions to bypass the fragmentation device 30. The fragmentation device 30 may also be operable in one or more intermediate modes of operation, e.g. whereby the degree of fragmentation is controllable (variable). The fragmentation device 30 can also be operable in higher order (MS^{N}) fragmentation modes of operation, e.g. whereby fragment ions are further fragmented one or more times by the fragmentation device 30.

The fragmentation device 30 can be any suitable type of fragmentation device, such as for example a collision induced dissociation (CID) fragmentation device, an electron induced dissociation (EID) fragmentation device, a photodissociation fragmentation device, and so on. Numerous other types of fragmentation are possible.

The mass analyser 40 is arranged downstream of the fragmentation device 30 and is configured to receive ions from the fragmentation device 30. Thus, the mass analyser 40 may receive unfragmented precursor ions and/or fragment ions, depending on the mode of operation of the fragmentation device 30. The mass analyser 40 is configured to analyse the received ions so as to determine their mass to charge ratio (m/z) and/or mass, i.e. to produce a mass spectrum of the ions. The mass analyser 40 can be any suitable type of mass analyser, such as an ion trap mass analyser, an electrostatic orbital trap mass analyser (such as an orbital trapping or Orbitrap™ FT mass analyser as made by Thermo Fisher Scientific), a time-of-flight (ToF) mass analyser such as a multi-reflecting time-of-flight (MR-ToF) mass analyser, or a quadrupole mass analyser. Numerous other types of mass analyser are possible.

It should be noted that FIG. 7 is merely schematic, and that the instrument can, and in embodiments does, include any number of one or more additional components such as ion optical devices. For example, the instrument may include one or more ion transfer stage(s) arranged between any of the illustrated components, e.g. including an atmospheric pressure interface and/or one or more ion guides, lenses and/or other ion optical devices configured such that some or all of the ions can be transmitted appropriately through the instrument. The ion transfer stage(s) may include any suitable number and configuration of ion optical devices, for example optionally including one or more ion guides, lenses and/or other ion optical devices.

In some embodiments, the instrument may include more than one mass analyser. For example, the instrument may be a dual mass analyser hybrid mass spectrometer of the type described in EP 3,410,463, the contents of which are incorporated herein by reference.

As also shown in FIG. 7, the instrument is under the control of a control unit 50, such as an appropriately programmed computer, which controls the operation of various components of the instrument and, for example, sets the voltages to be applied to the various components of the instrument. The control unit 50 may also receive and process data from various components including the analyser(s).

The instrument may be operable in various mode of operation. In particular, the instrument may be a tandem mass spectrometer operable in an MS1 mode of operation and an MS2 mode of operation.

In the MS1 (or “full mass scan”) mode of operation, the mass filter 20 is operated in its transmission mode of operation and the fragmentation device 30 is operated in its non-fragmentation mode of operation, e.g. so that a wide m/z range (e.g. full mass range) of unfragmented (“precursor” or “parent”) ions are analysed by the analyser 40 to produce an MS1 spectrum.

In the MS2 mode of operation, the mass filter 20 is operated in its filtering mode of operation and the fragmentation device 30 is operated in its fragmentation mode of operation, e.g. so that a selected narrow m/z range of precursor ions are fragmented and the resulting fragment (“product” or “daughter”) ions are analysed by the analyser 40 to produce an MS2 spectrum.

The instrument may also be operable in one or more higher order fragmentation modes of operation, such as for example an MS3 mode of operation, whereby precursor ions are fragmented, at least some of the resulting fragment ions are themselves fragmented, and the second-generation fragment ions (“granddaughter ions”) are analysed by the analyser 40 produce an MS3 spectrum. In general, the instrument may be operable in any order of fragmentation mode of operation, i.e. in an MS^{N} mode of operation where N≥2.

FIG. 8 shows schematically in more detail a mass spectrometer suitable for performing the approaches of various embodiments (in line with that shown in FIG. 7). The instrument is a hybrid instrument incorporating an MR-ToF analyser 40 (of the type described in U.S. Pat. No. 9,136,101), a quadrupole mass filter 20, and an orbital trapping or Orbitrap™ analyser 60. The instrument also includes an electrospray source 10, a collision cell 30, and the various ion guides etc. for a complete mass spectrometer. It will be understood that the instrument shown in FIG. 8 is a non-limiting example, and that numerous variations are possible.

In the embodiment depicted in FIG. 8, the instrument's ion source 10 is an electrospray ionisation (ESI) ion source. The instrument includes a vacuum interface, which includes a transfer tube 21, an ion funnel 22, a quadrupole pre-filter ion guide 23, and a so-called “bent flatapole” ion guide 24. The ion guide 24 may be of the design described in U.S. Pat. No. 9,536,722.

The instrument also includes a mass filter in the form of a quadrupole mass filter 20, an ion trap 31 in the form of a curved linear ion trap (“C-Trap”), and a collision cell 30 in the form of an ion routing multipole collision cell (“IRM”). Ions from the ion source 10 can be accumulated in the C-Trap 31 and/or collision cell 30 by opening and closing a gating electrode located in a charge detector assembly 26, which is arranged between the C-Trap 31 and the mass filter 20.

The instrument includes a time-of-flight (ToF) mass analyser 40 in the form of a multireflection time-of-flight (ToF) mass analyser. In the instrument depicted in FIG. 8, the analyser is of the tilted-mirror type described in U.S. Pat. No. 9,136,101, but it will be understood that any type of ToF analyser could be used.

As shown in FIG. 8, the instrument includes a multipole ion guide 32 to allow ions to be transferred from the collision cell 30 to the time-of-flight mass analyser 40. The time-of-flight mass analyser 40 includes an extraction trap 41, whereby ions are delivered from the collision cell 30 to the extraction trap 41 via the multipole ion guide 32. The ions are accumulated and cooled in the extraction trap 41.

The extraction trap 41 may incorporate two trapping regions, one at a relatively higher pressure for rapid ion cooling, and a second low pressure region for ion extraction. Ions are cooled in the high-pressure region and then transferred to the low-pressure region, where they are pulse ejected into the ToF analyser via a pair of deflectors 42. Ions oscillate between a pair of mirrors 43, which are tilted relative to one another so that the ion path is slowly deflected and redirected back to a detector 44. Correcting stripe electrodes 45 counter the loss of ion focus otherwise induced by the non-parallelism of the mirrors.

As also shown in FIG. 8, the instrument may optionally include a second mass analyser in the form of an electrostatic mass analyser 60, such as an orbital ion trap mass analyser, and more specifically an orbital trapping or Orbitrap™ FT mass analyser as made by Thermo Fisher Scientific. This hybridized instrument is described in more detail in U.S. Pat. No. 10,699,888, the contents of which are incorporated herein by reference.

Ions may be collected in the ion trap 31, and may then either be ejected orthogonally to the orbital trapping or Orbitrap™ analyser 60 for analysis without entering the collision or reaction cell 30, or the ions can be transmitted axially to the collision or reaction cell 30. Ions transmitted to the collision or reaction cell 30 can be either fragmented by collisions with a collision gas and/or a reagent in the collision cell 30, or merely cooled by collisions with a gas at lower energies that do cause the ions to fragment. Once accumulated in the collision cell 30, ions can be either be ejected into the mass analyser 40 for analysis (via the multipole ion guide 32), or ejected into the orbital trapping or Orbitrap™ analyser 60 for analysis (via the C-trap 31).

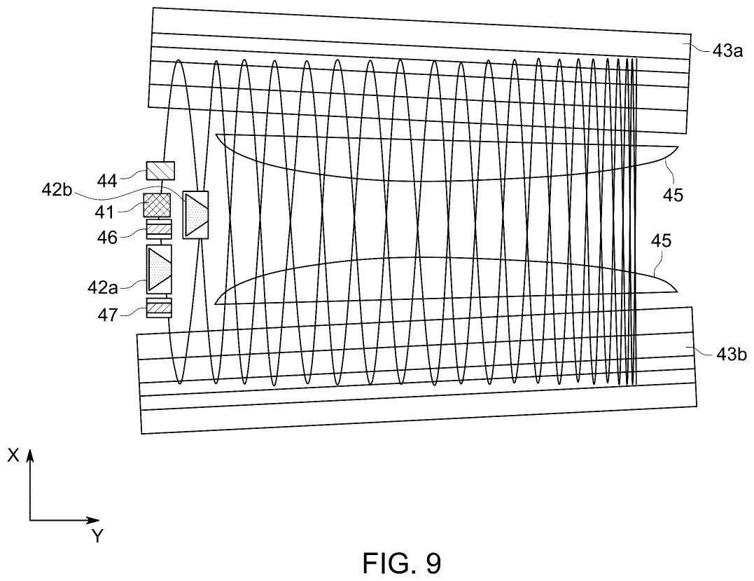

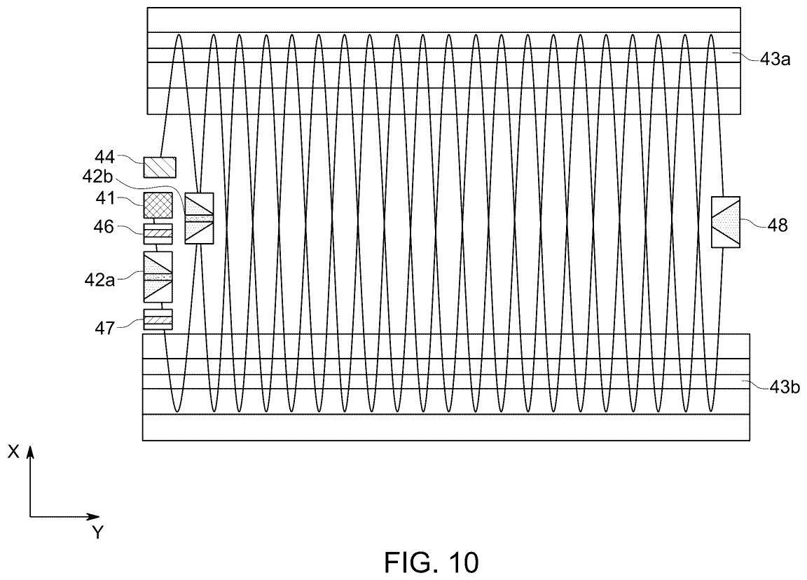

FIGS. 9 and 10 illustrate schematically detail of exemplary embodiments of the variable path length analyser 40. In these embodiments, the analyser 40 is a multi-reflecting time-of-flight (MR-ToF) mass analyser that is operable in a single-pass “normal” mode of operation, and a multi-pass “zoom” mode of operation.

As shown in FIGS. 9 and 10, the multi-reflection time-of-flight analyser 40 includes a pair of ion mirrors 43a, 43b that are spaced apart and face each other in a first direction X. The ion mirrors 43a, 43b are elongated along an orthogonal drift direction Y between a first end and a second end.

An ion source (injector) 41, which may be in the form of an ion trap, is arranged at one end (the first end) of the analyser. The ion source 41 may be arranged and configured to receive ions from the fragmentation device 30. Ions may be accumulated in the ion source 41, before being injected into the space between the ion mirrors 43a, 43b. As shown in FIGS. 9 and 10, ions may be injected from the ion source 41 with a relatively small injection angle or drift direction velocity, creating a zig-zag ion trajectory, whereby different oscillations between the mirrors 43a, 43b are separate in space.

One or more lenses and/or deflectors may be arranged along the ion path, between the ion source 41 and the ion mirror 43b first encountered by the ions. For example, as shown in FIGS. 9 and 10, a first out-of-plane lens 46, an injection deflector 42a, and a second out-of-plane lens 47 may be arranged along the ion path, between the ion source 41 and the ion mirror 43b first encountered by the ions. Other arrangements would be possible. In general, the one or more lenses and/or deflectors may be configured to suitably condition, focus and/or deflect the ion beam, i.e. such that it is caused to adopt the desired trajectory through the analyser.

The analyser 40 also includes another deflector 42b, which is arranged along the ion path, between the ion mirrors 43a, 43b. As shown in FIGS. 9 and 10, the deflector 42b may be arranged approximately equidistant between the ion mirrors 43a, 43b, along the ion path after its first ion mirror reflection (in ion mirror 43b), and before its second ion mirror reflection (in the other ion mirror 43a).

The analyser also includes a detector 44. The detector 44 may be any suitable ion detector configured to detect ions, and e.g. to record an intensity and time of arrival associated with the arrival of ion(s) at the detector. Suitable detectors include, for example, one or more conversion dynodes, optionally followed by one or more electron multipliers, and the like.

In its “normal” mode of operation, ions are injected from the ion source 41 into the space between the ion mirrors 43a, 43b, in such a way that the ions adopt a zigzag ion path having plural reflections between the ion mirrors 43a, 43b in the X direction, whilst: (a) drifting along the drift direction Y from the deflector 42b towards the opposite (second) end of the ion mirrors 43a, 43b, (b) reversing drift direction velocity in proximity with the second end of the ion mirrors 43a, 43b, and then (c) drifting back along the drift direction Y to the deflector 42b. The ions can then be caused to travel from the deflector 42b to the detector 44 for detection.

In the analyser of FIG. 9, the ions mirrors 43a, 43b are both tilted with respect to the X and/or drift Y direction. It would instead be possible for only one of the ion mirrors 43a, 43b to be tilted, and e.g. for the other one of the ion mirrors 43a, 43b to be arranged parallel to the drift Y direction. In general, the ion mirrors are a non-constant distance from each other in the X direction along most or all of their lengths in the drift direction Y. The drift direction velocity of ions towards the second end of the ion mirrors is opposed by an electric field resulting from the non-constant distance of the two mirrors from each other, and this electric field causes the ions to reverse their drift direction velocity in proximity with the second end of the ion mirrors and drift back along the drift direction towards the deflector.

The analyser depicted in FIG. 9, further comprises a pair of correcting stripe electrodes 45. Ions travelling down the drift length are slightly deflected with each pass through the mirrors 43a, 43b and the additional stripe electrodes 45 are used to correct for the time-of-flight error created by the varying distance between the mirrors. For example, the stripe electrodes 45 may be electrically biased such that the period of ion oscillation between the mirrors is substantially constant along the whole of the drift length (despite the non-constant distance between the two mirrors from). The ions eventually find themselves reflected back down the drift space and focused at the detector 44.

Further detail of the tilted-mirror type multireflection time-of-flight mass analyser of FIG. 9 is given in U.S. Pat. No. 9,136,101, the contents of which are incorporated herein by reference.

In the analyser of FIG. 10, the ion mirrors 43a, 43b are parallel to each other. In this embodiment, in order to cause the ions to reverse their drift direction velocity in proximity with the second end of the ion mirrors and drift back along the drift direction towards the deflector, the analyser includes a second deflector 48 at the second end of the ion mirrors 43a, 43b.

As also shown in FIG. 10, in this embodiment, a lens can be included in the injection deflector 42a and/or in the deflector 42b. Thus, the ion beam is allowed to expand a short way into the analyser before meeting a long-focus lens, which has the effect of focussing the ion beam along its length. The lens may be an elliptical drift focusing (converging) lens mounted within the deflector 42b. The second deflector 48, which may also include a lens, is used to reverse the beam direction whilst maintaining control of focal properties.

Further detail of the single-lens type multireflection time-of-flight mass analyser of FIG. 10 is given in UK Patent No. GB 2,580,089, the contents of which are incorporated herein by reference.

In the analysers depicted in FIGS. 9 and 10, the ion beam is allowed to spread out relatively broadly (in the drift direction Y) for most of its flight path. This is in contrast, for example, with multi-reflecting time-of-flight (MR-ToF) mass analysers which use a set of periodic lenses to focus the ion beam along its entire flight path, e.g. as described in the article A. Verenchikov, et al., Journal of Applied Solution Chemistry and Modelling, 2017, 6, 1-22. A significant advantage of allowing the ion beam to spread out broadly for most of its flight path is that space charge effects are reduced, which can be a significant problem for time-of-flight analysers, particularly when analysing labelled analyte ions. Nevertheless, embodiments described herein are also applicable to other MR-ToF analyser designs, such as the Verenchikov-type MR-ToF analyser.

In the embodiments depicted in FIGS. 9 and 10, the fact that the ion beam is relatively broad in the drift dimension Y means that the deflector 42b should be able to accept such a wide beam without introducing clipping or uneven deflection. A suitable deflector design is a trapezoid shaped or prism-like deflector.

Thus, the deflector 42b may comprise a trapezoid shaped or prism-like electrode arranged above the ion beam and another trapezoid shaped or prism-like electrode arranged below the ion beam. The electrodes may be located out-of-plane of the deflection, thereby allowing them to be easily made to be broad enough to accept a wide ion beam (at least compared to more conventional deflection plates that would sit at either side of the beam). The electrodes may be angled with respect to the ion beam, such that when suitable (DC) voltage(s) is (are) applied to the electrode(s), the resulting electric field induces a deflection in the ion beam. Ions may experience a relatively strong electric field at the edges of the angled electrodes, inducing a deflection. Suitable deflection voltages are of the order of ±a few volts, ±tens of volts, or ±hundreds of volts. The deflector should be (and in embodiments is) configured such that it can cause the ion beam to be deflected by a desired (selected) angle. The angle by which the ion beam is deflected by the deflector may be adjustable, e.g. by adjusting the magnitude of a (DC) voltage(s) applied to the deflector.

In embodiments, the multi-reflecting time-of-flight (MR-ToF) mass analyser is operable in a multi-pass “zoom” mode of operation. In this mode of operation, ions are made to make multiple cycles within the analyser in the drift direction Y. Increasing the number of cycles N increases the length of the ion path that ions take within the analyser (between the injector 41 and the detector 44), thereby increasing the resolution of the analyser. In the Verenchikov analyser, this may be done by controlling a voltage on an entrance lens. For the analysers depicted in FIGS. 9 and 10, the deflector 42b at the front of the analyser, which is normally used to reduce the injection angle and/or optimise the number of oscillations within a single drift pass, may (also) be used to reverse the drift direction velocity of the ions such that the ions are caused to complete a further cycle through the analyser.

Thus, in a multi-pass “zoom” mode of operation, ions are caused to complete plural (N) cycles within the analyser 40, where in each cycle the ions drift in the drift direction Y from the deflector 42b (or entrance lens) towards the opposite (second) end of the ion mirrors 43a, 43b, and then back to the deflector 42b (or entrance lens). In each cycle, the ions also complete plural reflections between the ion mirrors in the X direction. Thus, in each cycle, the ions adopt a zigzag ion path through the space between the ion mirrors 43a, 43b.

In the analysers depicted in FIGS. 9 and 10, an initial cycle may be initiated by injecting the ions from the injector 41 into the space between the ion mirrors 43a, 43b. The ions may be reflected in one of the ion mirrors 43b and may then travel to the deflector 42b. An appropriate (e.g. relatively small) voltage may be applied to the deflector 42b such that the ions are caused to exit the deflector 42b in a direction towards the second end of the ion mirrors. Upon existing the deflector 42b, the ions adopt a zigzag ion path having plural reflections between the ion mirrors 43a, 43b in the direction X whilst: (a) drifting along the drift direction Y from the deflector 42b towards the second end of the ion mirrors, (b) reversing drift direction velocity in proximity with the second end of the ion mirrors, and (c) drifting back along the drift direction Y to the deflector 42b.

After the ions have completed this initial cycle, each further cycle is initiated by using the deflector 42b to reverse the drift direction velocity of the ions (in proximity with the first end of the ion mirrors). To do this, an appropriate voltage may be applied to the deflector 42b that causes ions to leave the deflector 42b with a drift direction velocity opposite to the drift direction velocity with which the ions originally entered the deflector 42b. This voltage may be applied during a time period in which it is expected that the ions will arrive back at the deflector 42b. Suitable deflection voltages to reverse the drift direction of the ions are of the order of hundreds of volts.

The deflector may be used to reverse the drift direction velocity of the ions one or more times. Thus, the method may comprise causing the ions to complete plural (N) cycles within the analyser, where the first cycle is initiated by injecting the ions into the space between the ion mirrors, and after the ions have completed the first cycle, each further cycle may be initiated by using the deflector to reverse the drift direction velocity of the ions.

After the ions have completed the desired (plural) number (N) of cycles within the analyser, the ions are allowed to travel from the deflector 42b to the detector 44 for detection. To do this, an appropriate voltage may be applied to the deflector 42b such that the ions are caused to exit the deflector 42b in a direction towards the detector 44. The ions may be reflected in (the other) one of the ion mirrors 43a before travelling to (and being detected by) the detector 44.

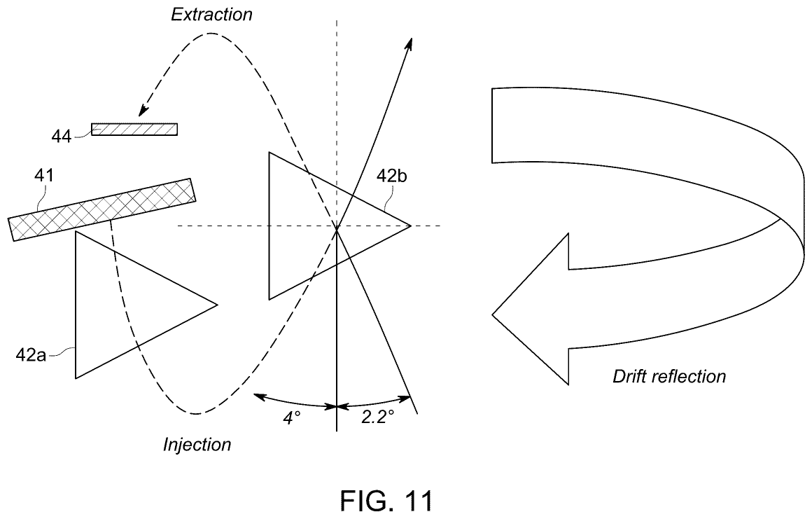

FIG. 11 illustrates schematically this zoom mode of operation. As shown in FIG. 11, ions are injected from the ion trap source 41, through a deflector 42a and between the mirrors at a relatively high angle. After the first half oscillation, ions pass a second prism shaped deflector 42b that reduces the injection angle by almost half. Oscillating ions then drift up the elongate mirror length and are turned back, e.g. by the mirrors'set tilt in the case of the analyser of FIG. 9. By the time ions return to this second deflector 42b the voltage may be switched from an injection/extraction potential of approximately −150V to a trapping potential of approximately +350V, which reflects the ion beam back into the analyser body for a second pass. After a desired number of passes (N) have been traversed by the ions, the deflector 42b is switched back to the injection/extraction potential and ions escape to the detector 44.

In the general terms discussed above, the ion optical device may comprise a variable path length ion analyser (for example, a multi-reflecting time of flight mass analyser) having an electrostatic lens and/or deflector, optionally positioned at an entrance to the analyser. Then, the power supply may be configured to supply a voltage to the electrostatic lens and/or deflector. Advantageously, the voltage supplied to the electrostatic lens and/or deflector is selectable between: a first voltage, causing ions to be injected to and/or extracted from the variable path length ion analyser; and a second voltage, causing reversal of a drift direction velocity of ions being analysed by the variable path length ion.

Although a number of embodiments have been described, the skilled person will appreciate that modifications and variations are possible. For example, different circuits may be implemented based on the principles explained above.

As used herein, including in the claims, unless the context indicates otherwise, singular forms of the terms herein are to be construed as including the plural form and vice versa. For instance, unless the context indicates otherwise, a singular reference herein including in the claims, such as “a” or “an” (such as an ion multipole device) means “one or more” (for instance, one or more ion multipole device). Throughout the description and claims of this disclosure, the words “comprise”, “including”, “having” and “contain” and variations of the words, for example “comprising” and “comprises” or similar, mean “including but not limited to”, and are not intended to (and do not) exclude other components.

The use of any and all examples, or exemplary language (“for instance”, “such as”, “for example” and like language) provided herein, is intended merely to better illustrate the invention and does not indicate a limitation on the scope of the invention unless otherwise claimed. No language in the specification should be construed as indicating any non-claimed element as essential to the practice of the invention.

Any steps described in this specification may be performed in any order or simultaneously unless stated or the context requires otherwise.

All of the aspects and/or features disclosed in this specification may be combined in any combination, except combinations where at least some of such features and/or steps are mutually exclusive. As described herein, there may be particular combinations of aspects that are of further benefit, such the aspects of ion guides for use in mass spectrometers and/or ion mobility spectrometers. In particular, the preferred features of the invention are applicable to all aspects of the invention and may be used in any combination. Likewise, features described in non-essential combinations may be used separately (not in combination).

1. An amplifier arrangement for providing a varying electrode voltage to an ion optical device, the amplifier arrangement comprising:
a high-speed amplifier, configured to receive an input to the amplifier arrangement and provide a low voltage output; and
a low-speed controllable voltage source, arranged to float on the low voltage output and configured to provide a high voltage output of the amplifier arrangement;
wherein the high voltage output of the amplifier arrangement is fed back for control of the high-speed amplifier.

2. The amplifier arrangement of claim 1, wherein the high-speed amplifier comprises a differential amplifier.

3. The amplifier arrangement of claim 2, wherein the differential amplifier is configured to receive the input to the amplifier arrangement at a first input and the high voltage output of the amplifier arrangement at a second input.

4. The amplifier arrangement of claim 1, wherein the low-speed controllable voltage source is configured to be controlled by a control signal derived from the input to the amplifier arrangement and/or the low voltage output of the high-speed amplifier.

5. The amplifier arrangement of claim 4, further comprising:
a second amplifier, configured to receive a signal based on the low voltage output of the high-speed amplifier as an input and generate the control signal based on the received signal.

6. The amplifier arrangement of claim 5, further comprising:
a feedback amplifier, configured to receive the low voltage output of the high-speed amplifier as an input and provide the signal based on the low voltage output of the high-speed amplifier to the second amplifier.

7. The amplifier arrangement of claim 5, wherein the second amplifier is configured to receive the input to the amplifier arrangement adjusted by the signal based on the low voltage output of the high-speed amplifier.

8. The amplifier arrangement of claim 1, wherein the low-speed controllable voltage source comprises a galvanic isolated power supply.

9. The amplifier arrangement of claim 1, wherein the low-speed controllable voltage source comprises a voltage-controlled voltage source or a current source with a floating capacitor.

10. A power supply for supplying at least one voltage to an electrode of an ion optical device, comprising the amplifier arrangement of claim 1.

11. An ion analytical system comprising:
an ion optical device; and
the power supply of claim 10, configured to supply at least one voltage to an electrode of the ion optical device.

12. The ion analytical system of claim 11, wherein the ion optical device is a multipole mass filter or comprises one or more electrostatic lenses and/or deflectors.

13. The ion analytical system of claim 12, wherein the ion optical device comprises a variable path length ion analyser having an electrostatic lens and/or deflector, the power supply being configured to supply a voltage to the electrostatic lens and/or deflector.

14. The ion analytical system of claim 13, wherein the voltage supplied to the electrostatic lens and/or deflector is selectable between: a first voltage, causing ions to be injected to and/or extracted from the variable path length ion analyser; and a second voltage, causing reversal of a drift direction velocity of ions being analysed by the variable path length ion analyser.

15. The ion analytical system of claim 11, wherein the ion optical device forms part of a mass spectrometer.

16. The ion analytical system of claim 15, wherein the mass spectrometer is a Time of Flight (TOF) mass spectrometer, a hybrid mass spectrometer or a Fourier Transform Mass Spectrometer (FTMS).
